(19) United States
(12) Patent Application Publication
(10) Pub. No.: US 2013/0249580 A1
(43) Pub. Date: Sep. 26, 2013

(54) APPARATUS AND METHOD FOR EVALUATING CHARACTERISTICS OF A PHOTOVOLTAIC DEVICE

(71) Applicants: Weston Alan Dobson, Arvada, CO (US); Christopher Rathweg, Louisville, CO (US)

(72) Inventors: Weston Alan Dobson, Arvada, CO (US); Christopher Rathweg, Louisville, CO (US)

(73) Assignee: PRIMESTAR SOLAR, INC., Arvada, CO (US)

(21) Appl. No.: 13/429,699

(22) Filed: Mar. 26, 2012

(51) Int. Cl. G01R 31/26

(52) U.S. Cl. 324/750.16; 324/761.01

(57) ABSTRACT

An apparatus is provided for evaluating characteristics of a photovoltaic device with an exposed back contact layer having a plurality of electrically discrete areas arranged in a grid. The apparatus may include, for example, a light source for illuminating the photovoltaic device and a probe head assembly having a plurality of probes arranged in a grid corresponding to the grid on the photovoltaic device so that a given pair of the probes corresponds to a respective one of the electrically discrete areas within the grid. The probes and photovoltaic device may be positionable so that the probes contact the back contact layer. Related methods for evaluating characteristics are also provided.

### FIELD OF THE INVENTION

The present disclosure relates generally to apparatus and methods for evaluating characteristics of photovoltaic devices.

### BACKGROUND OF THE INVENTION

Thin film photovoltaic (PV) devices (also known as “solar panels”), such as those, for example, based on cadmium telluride (CdTe) paired with cadmium sulfide (CdS) as the photo-reactive components, are gaining wide acceptance and interest in the industry. CdTe is a semiconductor material having characteristics particularly suited for conversion of solar energy to electricity. The junction of the n-type layer and the p-type layer is generally responsible for the generation of electric potential and electric current when the CdTe PV module is exposed to light energy, such as sunlight. Specifically, the CdTe layer and the CdS layer form a p-n heterojunction where the CdTe layer acts as the p-type layer receiving electrons from the CdS layer, acting as the n-type layer.

Typically, such PV modules are built on a glass sheet with a transparent conductive oxide (TCO) layer applied to it. The TCO layer provides the front electrical contact used to collect and carry current. A resistant transparent layer may be placed over the TCO layer to act as a buffer before the CdS and CdTe layers described above are applied. One or more layers are applied to the CdTe layers. For example, a back contact layer can be provided to collect and carry current. An encapsulating layer may be provided atop the back contact layer along with electrical connecting strips, insulating strips, adhesive elements, etc. A back glass sheet is then applied, with the various layers being held between the front glass sheet and back glass sheet.

At certain points in the process of applying layers to the front glass, laser scribing applied at different depths is used to divide the layers into multiple individual cells connected in series. For example, a first series of scribes can be directed through layers from CdTe through TCO to initially divide cells at the TCO layer. Such scribes can be filled with non-conductive material when a coating is applied to the CdTe layer. A second series of scribes can be applied to this coating down through the buffer layer (i.e., all existing layers except the TCO layer). This series of scribes can be filled with material when the back contact later is applied, thereby placing the TCO layer in electrical contact with the back contact layer via this second series of scribes, as filled with conductive material. A thin set of scribes can be then made through the back contact layer down though the CdS layer. This set of scribes is filled with a non-conductive material or left empty, thereby electrically separating the CdS and CdTe layers completely into individual cells attached in series via the from and back conductive layers. U.S. patent application Ser. No. 12/825,800, filed Jun. 29, 2010, describes such a cell structure, and in incorporated by reference herein for all purposes. It should be understood, however, that many types of PV modules, including those based on, for example, CdTe, cadmium-indium-gallium-selenide (CIGS), or amorphous silicon (a-Si) technologies, with their corresponding variations in layering and laser scribing have been proposed, and that the present disclosure could be used with many different types of such modules.

As is typical in most industries, PV modules are tested in various ways to evaluate production quality. For example, a common test is to expose the PV module to light and take performance measurements, for example to determine the voltage and current generated by a known light input. While these tests are very useful, the tests do not give information about individual portions or regions of the PV module, only information as to the module as a whole. In view of the complexity of the sequential deposition and removal of materials during the various steps, many variables come into play, and an overall result as to performance for a whole module provides only limited information as to the effectiveness or accuracy of the many individual production steps. Accordingly, a testing method and apparatus that would provide more detailed and location-specific performance data for a PV module would be welcome.

### BRIEF DESCRIPTION OF THE INVENTION

Aspects and advantages of the invention will be set forth in part in the following description, or may be obvious from the description, or may be learned through practice of the invention.

According to certain aspects of the disclosure, an apparatus is provided for evaluating characteristics of a photovoltaic device with an exposed back contact layer having a plurality of electrically discrete areas arranged in a grid. The apparatus may include, for example, a light source for illuminating the photovoltaic device and a probe head assembly having a plurality of probes arranged in a grid corresponding to the grid on the photovoltaic device so that a given pair of the probes corresponds to a respective one of the electrically discrete areas within the grid. The probes and photovoltaic device may be positionable so that the probes contact the back contact layer. A controller may direct positioning of the probes into contact with the photovoltaic device, activating the light source, and receiving information from probes generated when the light source is activated. Various options and modifications are possible.

According to certain other aspects of the disclosure, a method is provided for evaluating characteristics of a photovoltaic device with an exposed back contact layer. The method may include, for example: scribing the photovoltaic device with a first plurality of parallel scribes in a first direction to a depth through the back contact layer to create a series of discrete linear cells electrically connected in series; scribing the photovoltaic device with a second plurality of parallel scribes in a second direction substantially perpendicular to the first direction to a depth through the back contact layer to electrically isolate material on opposite sides of the second plurality of parallel scribes; contacting the back contact layer with a plurality of probes arranged in a grid of discrete areas at least partially defined by the second scribing step; illuminating the photovoltaic device; and receiving information from the probes. As above, various options and modifications are possible.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 provides a general schematic of a cross-sectional view of one possible thin film photovoltaic device that could be used in the disclosed methods and apparatus before cross-scribing;

FIG. 2 provides a perspective view of the photovoltaic device of FIG. 1 before cross-scribing;

FIG. 3 provides a perspective view of the photovoltaic device of FIG. 1 after cross-scribing;

FIG. 4 provides a perspective view of a device for evaluating characteristics of a photovoltaic device as in FIGS. 1-3 with the probe head in a retracted position before placement of the photovoltaic device;

FIG. 5 provides a perspective view of the device of FIG. 4, after placement of the photovoltaic device;

FIG. 6 provides a perspective view of the device of FIG. 4, with the probe head moved laterally above the photovoltaic device;

FIG. 7 provides a partial schematic side view of the device of FIG. 4, with the probe head above the photovoltaic device;

FIG. 8 provides a partial schematic side view as in FIG. 7, with the probe head lowered into contact with the photovoltaic device;

FIG. 9 provides a partial schematic perspective view of the device of FIG. 4, showing spacing of probes atop the photovoltaic device;

FIG. 10 provides a top schematic view of a photovoltaic device and probe arrangement;

FIG. 11 provides one possible resulting property map of a photovoltaic device evaluated according to the disclosed apparatus and method; and

FIG. 12 provides another possible resulting property map of a photovoltaic device evaluated according to the disclosed apparatus and method.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise expressly stated. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

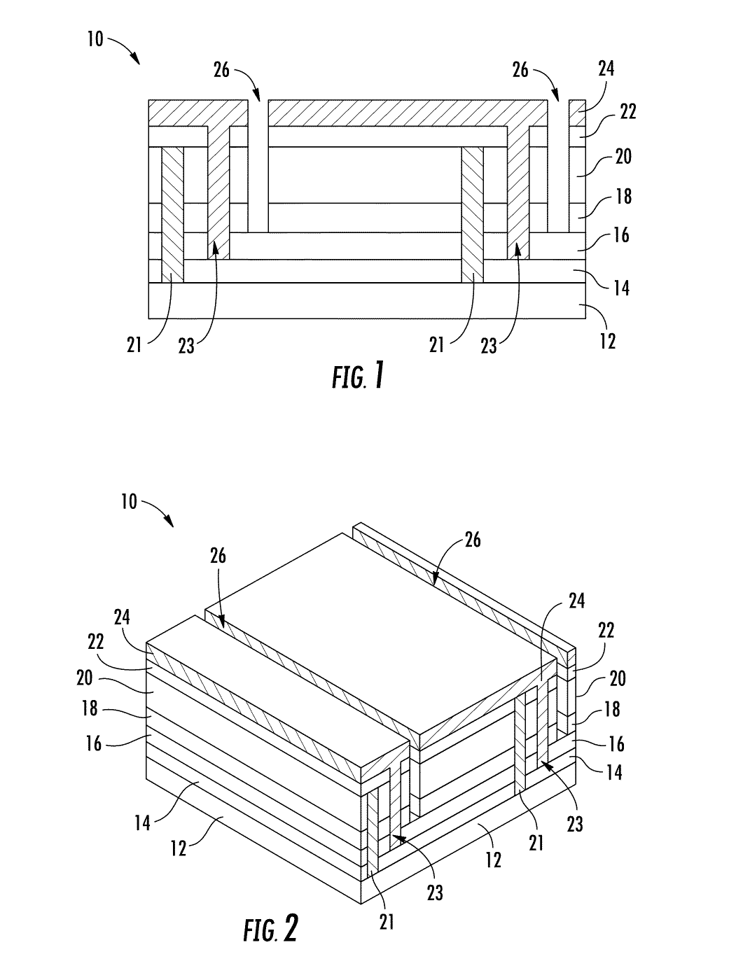

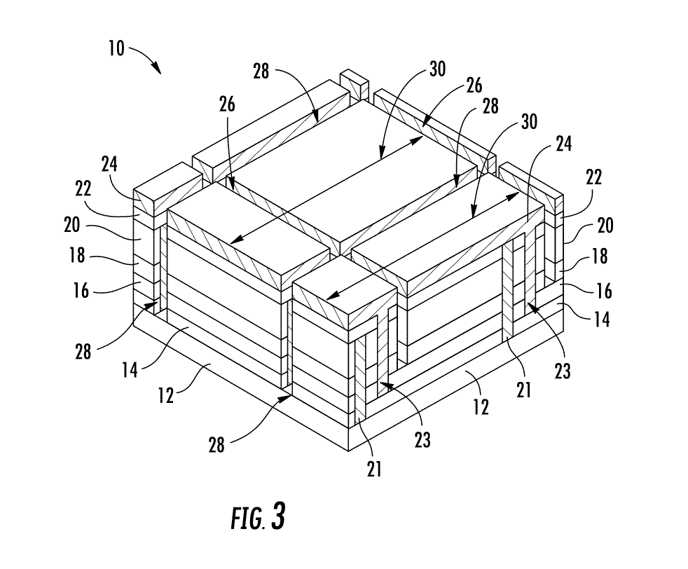

FIGS. 1-3 show closeup schematic views of a portion of a photovoltaic device 10 that may be evaluated using the disclosed methods and apparatus. It should be understood that device 10 is merely one example and numerous types of thin film photovoltaic devices could be evaluated within the scope of the present invention. Accordingly, with minor exception noted below, virtually any type of thin film photovoltaic device could be employed. However, for purposes of illustration only, a cadmium telluride based thin-film photovoltaic device 10, in particular, is employed for testing.

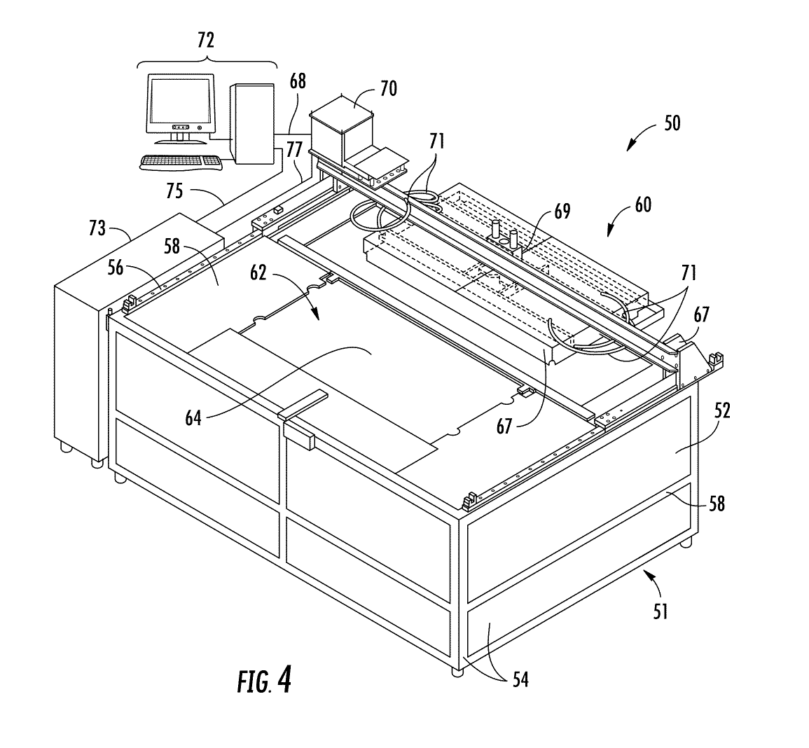

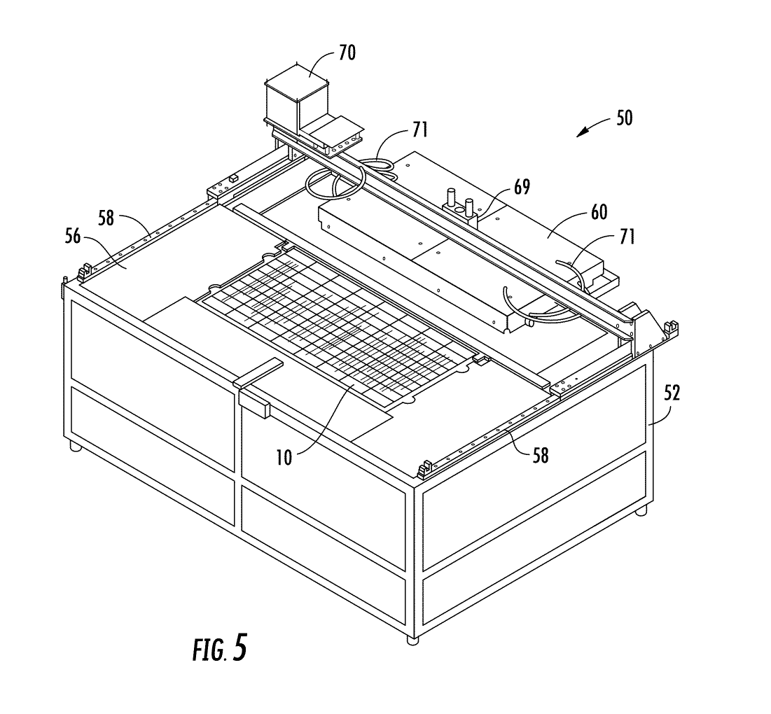

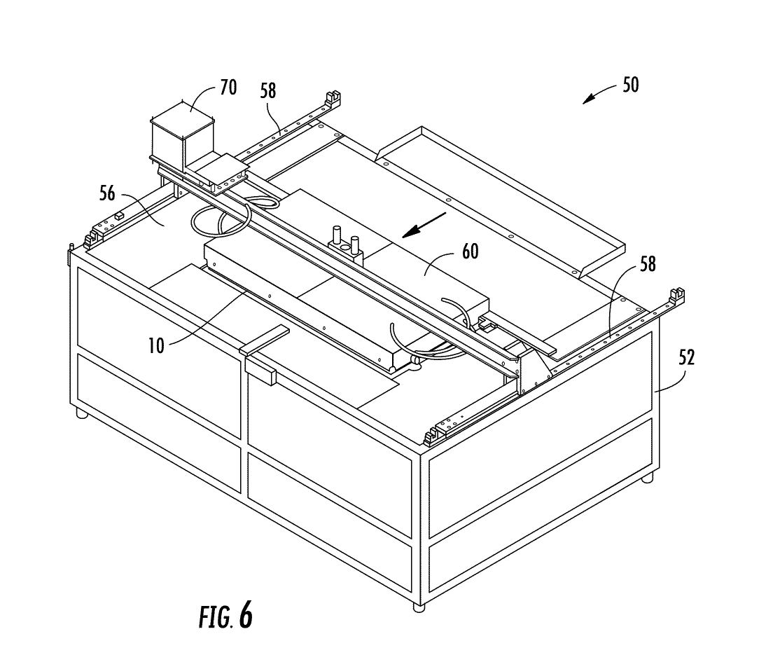

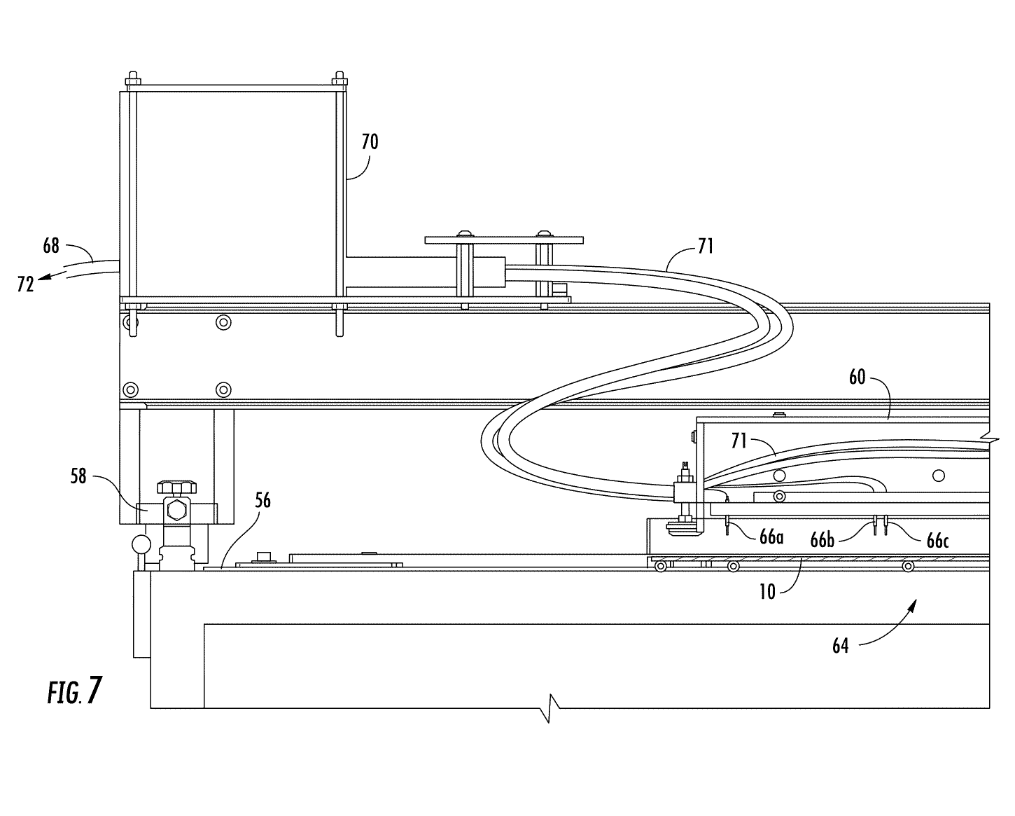

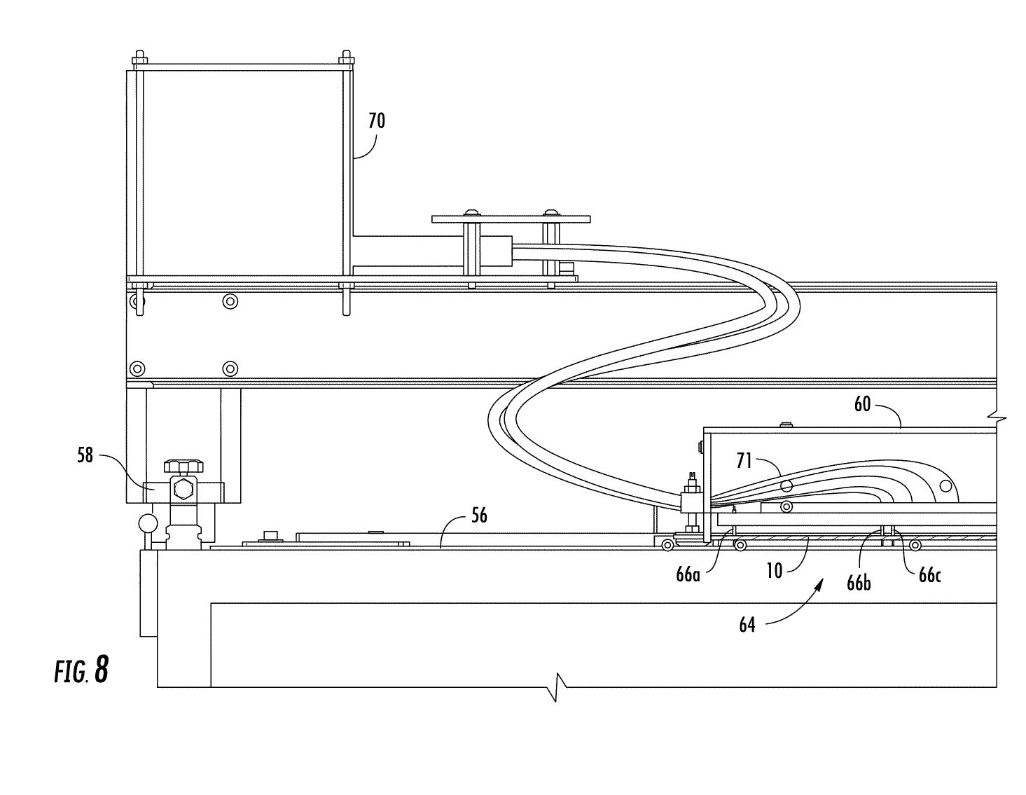

FIGS. 4-10 illustrate one embodiment of an apparatus 50 that could be used to test device 10. It should be understood that apparatus 50, and the methods of use of such apparatus or others disclosed herein, are also but examples provided for purposes of explanation. Other apparatus and methods of testing could be employed.

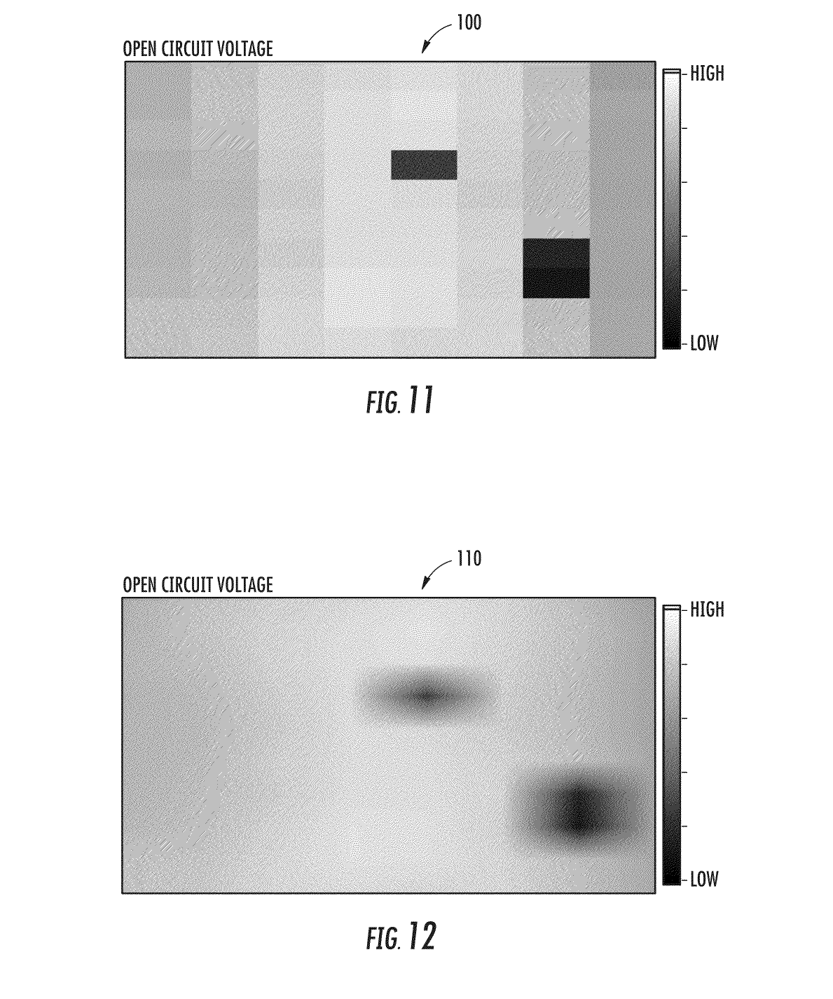

FIGS. 11 and 12 illustrate two examples of maps of properties of a tested device 10 that could be created using the apparatus and methods disclosed herein. Again, other resulting maps, data sets, whether visual, numerical or otherwise, could also result.

Turing first to the device 10 to be measured, FIGS. 1-3 illustrate a cadmium telluride based thin-film photovoltaic device 10 including a transparent substrate 12 (e.g., a glass substrate), a TCO layer 14, a resistive transparent buffer layer 16, a cadmium sulfide layer 18, a cadmium telluride layer 20, a graphite layer 22, and a metal contact layer 24.

The photovoltaic device 10 generally includes a plurality of cells separated by first scribe lines, generally formed via a laser scribing process. Second cross-scribe lines can be added, as discussed below, not for purposes of usage of device 10, but for purposes of testing according to the present disclosure. To understand the discrete elements that may be tested according to the present disclosure, a detailed description of a typical device 10 is provided herein, along with discussion of added cross-scribe lines for use by the present apparatus and method.

The first scribe lines can be created, for example, by a laser scribing process that may define a first isolation scribe through the photo reactive layers (i.e., the cadmium sulfide layer 18 and the cadmium telluride layer 20) and underlying layers (i.e., through the buffer layer 16 and TCO layer 14) down to the glass substrate 12. The first isolation scribe line is then filled with dielectric material 21 before application of the back contact layers 22, 24, in order to ensure that the TCO layer 14 is electrically isolated between cells. For example, the first isolation scribe 21 can be filled using a photoresist development process, wherein a liquid negative photoresist (NPR) material is coated onto the cadmium telluride layer 20 by spraying, roll coating, screen printing, or any other suitable application process. The substrate 12 is then exposed to light from below such that the NPR material in the first isolation scribes 21 (and any pinholes in the cadmium telluride material 20) are exposed to the light, causing the exposed NPR polymers to crosslink and “harden.” The substrate 12 is then “developed” in a process wherein a chemical developer is applied to the cadmium telluride layer 20 to dissolve any unhardened NPR material. In other words, the NPR material that was not exposed to the light is washed away from the cadmium telluride layer 20 by the developer, leaving the first isolation scribes 21 filled with the NPR material.

A series connecting scribe 23 can be laser cut through the graphite layer 22 to the TCO layer 14 and filled with the conductive metallic material of the metal contact layer 24 to electrically connect adjacent cells to each other in series. Of course, any conductive material can be included in the series connecting scribes 23. Specifically, the series connecting scribe 23 can allow the metal contact layer 24 to contact the TCO layer 14 providing a direct electrical connection between the back contact (i.e., the graphite layer 22 and the metal contact layer 24) and the front contact material (i.e., the TCO layer 14).

Finally, a second isolation scribe 26 can be laser cut through the back contact (i.e., the graphite layer 22 and the metal contact layer 24) and photo reactive layers (i.e., the cadmium sulfide layer 18 and the cadmium telluride layer 20) to isolate the back contact into individual cells. Alternatively, a given first isolation scribe 21, series connecting scribe 23, or second isolation scribe 26 could instead be, e.g., mechanically or chemically (e.g., via a selective etch/mask) formed and still be within the scope of the present system.

The exemplary device 10 of FIGS. 1-3 includes a top sheet of glass 12 employed as the substrate. In this embodiment, the glass 12 can be referred to as a “superstrate,” since it is the substrate on which the subsequent layers are formed, though it faces upwards to the radiation source (e.g., the sun) when the cadmium telluride thin film photovoltaic device 10 is in use. During evaluation via the disclosed methods and apparatus, glass 12 is exposed to light from the apparatus. The top sheet of glass 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the glass 12 can be a low iron float glass containing less than about 0.15% by weight iron (Fe), and may have a transmissiveness of about 0.9 or greater in the spectrum of interest (e.g., wavelengths from about 300 nm to about 900 nm).

The transparent conductive oxide (TCO) layer 14 is shown on the glass 12 of the exemplary device 10. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). The TCO layer 14 generally includes at least one conductive oxide, such as tin oxide, zinc oxide, or indium tin oxide, or mixtures thereof. Additionally, the TCO layer 14 can include other conductive, transparent materials. The TCO layer 14 can also include zinc stannate and/or cadmium stannate. The TCO layer 14 can be formed by sputtering, chemical vapor deposition, spray pyrolysis, or any other suitable deposition method.

The resistive transparent buffer layer 16 (RTB layer) is generally more resistive than the TCO layer 14 and can help protect the device 10 from shunting interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.0 eV). The RTB layer 16 can include, for instance, a combination of zinc oxide (ZnO) and tin oxide (SnO₂), which can be referred to as a zinc tin oxide layer (“ZTO”).

The cadmium sulfide layer 18 is shown on resistive transparent buffer layer 16 of the exemplary device 10. The cadmium sulfide layer 18 is an n-type layer that generally includes cadmium sulfide (CdS) but may also include other materials, such as zinc sulfide, cadmium zinc sulfide, etc., and mixtures thereof as well as dopants and other impurities. In one particular embodiment, the cadmium sulfide layer may include oxygen up to about 25% by atomic percentage, for example from about 5% to about 20% by atomic percentage. The cadmium sulfide layer 18 can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent or window layer on the device 10. The cadmium sulfide layer 18 can be formed by sputtering, chemical vapor deposition, chemical bath deposition, and other suitable deposition methods.

The cadmium telluride layer 20 is shown on the cadmium sulfide layer 18 in the exemplary cadmium telluride thin film photovoltaic device 10 of FIG. 1. The cadmium telluride layer 20 is a p-type layer that generally includes cadmium telluride (CdTe) but may also include other materials. As the p-type layer of device 10, the cadmium telluride layer 20 is the photovoltaic layer that interacts with the cadmium sulfide layer 18 (i.e., the n-type layer) to produce current from the adsorption of radiation energy by absorbing the majority of the radiation energy passing into the device 10 due to its high absorption coefficient and creating electron-hole pairs. For example, the cadmium telluride layer 20 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) to the n-type side (i.e., the cadmium sulfide layer 18).

A series of post-forming treatments can be applied to the exposed surface of the cadmium telluride layer 20. These treatments can tailor the functionality of the cadmium telluride layer 20 and prepare its surface for subsequent adhesion to the back contact layers 22 and 24. For example, the cadmium telluride layer 20 can be annealed at elevated temperatures, and copper can be applied to the exposed surface of the cadmium telluride layer 20.

The back contact is formed, for example, from the graphite layer 22 and the metal contact layer 24 shown on the cadmium telluride layer 20 and generally serves as the back electrical contact, in relation to the opposite, TCO layer 14 serving as the front electrical contact. The back contact is formed on, and in one embodiment is in direct contact with, the cadmium telluride layer 20. It is, of course, understood that alternative back contact layers are available, and such materials are considered to be within the scope of the present system.

The graphite layer 22 of exemplary device 10 can include a polymer blend or a carbon paste, or other materials, and can be applied to the semiconductor device by any suitable method for spreading the blend or paste, such as screen printing, spraying, or by a “doctor” blade. After the application of the graphite blend or carbon paste, the device 10 can be heated to convert the blend or paste into the conductive graphite layer 22. The graphite layer 22 can be, in particular embodiments, from about 0.1 μm to about 10 μm in thickness, for example from about 1 μm to about 5 μm.

The metal contact layer 24 is suitably made from one or more highly conductive materials, such as elemental nickel, chromium, copper, tin, aluminum, gold, silver, technetium, or alloys or mixtures thereof. The metal contact layer 24, if made of or comprising one or more metals, is suitably applied by a technique such as sputtering or metal evaporation. The metal contact layer 24 can be from about 0.1 μm to about 1.5 μm in thickness.

Other components (not shown) can be included in the exemplary device 10, such as buss bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically-generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells, so as to add scribe lines 26.

Typically, a commercial embodiment would also include the buss bars, wiring, insulation, etc., as well as a second sheet of glass (not shown) or other rear cover placed on rear contact layer 24. However, the present evaluation process and apparatus may employ a photovoltaic device without such second sheet in place so that various locations on rear contact layer 24 are electrically exposed. It should be understood that other arrangements for obtaining access to rear contact layer 24 are within the scope of the present disclosure, such as providing or creating spaced openings, passageways, electrical contacts, etc.

As shown in FIG. 3, for purposes of the present testing apparatus and methods at least one cross scribe 28 is created through all layers of device 10 including back contact 24 through front contact 14. A plurality of such scribes 28 can be created, for example, via a laser, mechanical, or chemical means, as described above regarding other scribes 21, 23 and 26. Scribes 28 as shown are substantially perpendicular to scribes 21, 23 and 26, and form elements 30 in a grid on device 10. As scribes 28 pass entirely through all layers except for glass 12, each scribe electrically isolates the elements 30 on opposite sides of the scribe. Therefore, if one scribe 28 were employed across device 10, two such areas would be created. If as shown nine scribes 28 were employed across device 10, ten such electrically isolated elements 30 extending lengthwise across the device would be created. Effectively, each element 30 comprises a photovoltaic device with a plurality of cells created by portions of the scribes 21, 23 and 26 arranged in series. Such scribes 28 might effectively destroy or impair the ability of device 10 to function as a photovoltaic device without additional electrical connections or the like. Therefore, the present apparatus and methods might be considered a destructive testing system for use in evaluating the qualities of photovoltaic devices created in an assembly line, not necessarily for forming devices that will be used commercially, unless the devices were altered in some way to account for the additional electrical isolation.

FIG. 4 shows a testing apparatus 50 useful in carrying out the disclosed methods. As shown, apparatus 50 includes a light cabinet 51 having an outer frame 52 with sides 54 and a top surface 56. Rails 58 along edges of top surface 56 can be used to position probe head assembly 60 either in a retracted position (see FIG. 4) or above a testing area 62 (see FIG. 6). Probe head assembly 60 can be moved back and forth along rails 58 by any suitable means such as hydraulics, pneumatics, servomotors, or manual placement. When probe head assembly 60 is in the retracted position, photovoltaic devices 10 can be placed on or removed from testing area 62 by conventional handling machinery such as rollers, conveyors, suction cups, etc. Alternatively, photovoltaic devices 10 can be placed and removed by hand.

An actuator 69 can be used to raise and lower head assembly 60 relative to cabinet 51. Actuator 69 can be a hydraulic, pneumatic, servomotor or manual device. Alternatively, photovoltaic device 10 can be raised or lowered relative to head assembly 60, if desired, using any suitable mechanism.

Testing area 62 of light cabinet 51 is covered by a transmissive surface portion of a light source 64, housed below within frame 52. Typically, such light sources 64 are made to provide light across a spectrum to mimic outside solar light that would impinge upon a photovoltaic device, although lighting devices with other transmission spectra could be employed.

Probe head assembly 60 has a plurality of probes (generally) 66 arranged in a grid sized to match all or part of photovoltaic device 10. Probes 66 are all electrically connected by wiring 68,71 via a multiplexer 70 to a general purpose computer 72, and by wiring 71,77 via the multiplexer 70 to an electrical control cabinet 73, connected in turn to computer 72 via wiring 75. Moving probe head assembly 60 downward via the actuator 69 so to that probes 66 contact photovoltaic device 10 (or moving device 10 upward to contact probes 66) places the probes in electrical contact with the device 10 at the points of contact. When light is provided by light source 64, pairs of probes 66 (i.e., matched pairs of positive and negative electrodes) can be used to detect current, voltage, etc., as described below.

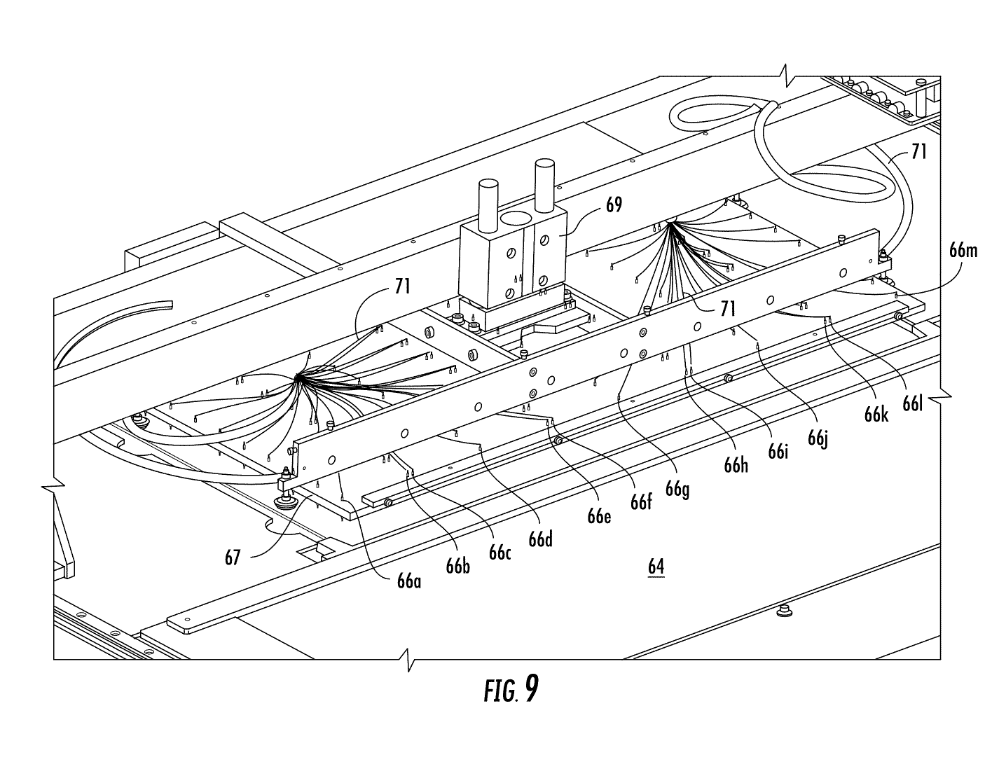

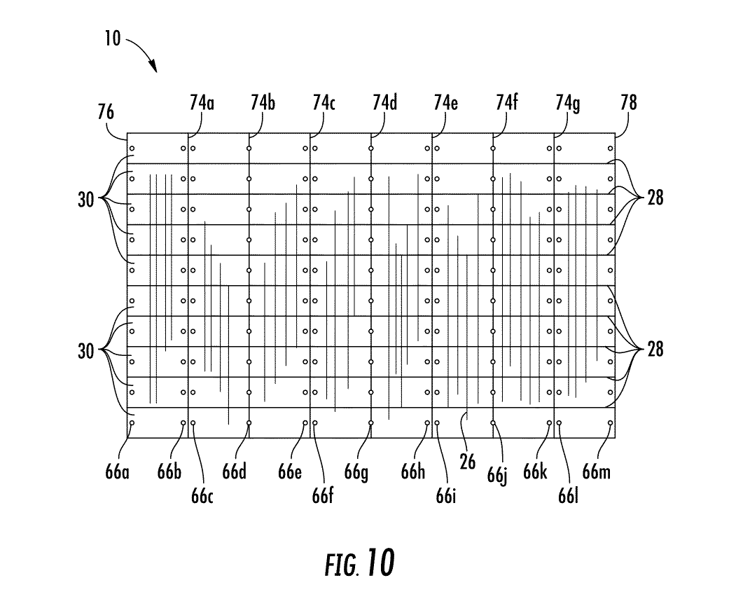

As shown in FIGS. 9 and 10, locations of probes 66 correspond to locations of edges of individual grid sections which can be defined in various ways on the photovoltaic device 10. As shown in this example, thirteen probes 66a-66m are provided, some individually (e.g., 66a) and some in close pairs (e.g., 66b and 66c).

The placement of probes 66 and the number of cross-scribes 28 can be arranged in various ways to obtain information about the photovoltaic device 10, as desired. For example, depending on the number of discrete areas or voltaic device desired to be tested, the number of probes 66 and cross-scribes 28 can be altered. Also, the number of calls in photovoltaic device 10 created by isolation scribes and the dielectric fill material 21 may impact the decisions as to how to arrange the probes 66 and cross-scribes 28. The channel capacity of the multiplexer used may also be a factor as to how many individual measurable discrete areas as created, or how many are measured at once. Preferably all cells of photovoltaic device can be measured by probes, but certain cells could be excluded as desired to achieve a given spacing, a given uniformity of size if elements measured, the multiplexer capacity, etc. Therefore, the type and arrangement of the tested cells 30 can vary greatly, depending on the user.

A grid section could comprise an entire isolated element 30 extending across device 10 substantially from side 76 to side 78. For example, cross-scribes 28 and probes 66a and 66m can define such a grid section. As shown, probes 66a have a first polarity (e.g., negative) and probes 66m have an opposite polarity (e.g., positive). However, any of the probes 66a-66m could, in fact, act as either a positive or negative depending on the situation or placement. In any given pair used to test a grid section, one probe will be negative and the other positive. If all of probes 66a and 66m were used (and no others), then the embodiment of FIG. 10 would create ten separate grid sections, each corresponding to an entire isolated element 30. Accordingly, when light is provided by element 64, separate information as to each of the ten grid areas 30 (linear areas between sides 76 and 78, as divided by cross-scribes 28) would be provided via probes 66a and 66m. Depending on the capacity of the multiplexer 70, the controller such as a computer 72, etc., such information could be obtained in a single instance of illumination or multiple instances. Computer 72 can process the information received from probes 66a and 66m to map the characteristics (e.g., efficiency, V_{oc}, I_{sc} Rₛₕ, Rₛ, fill factor, etc.) of the device.

Alternatively, smaller portions of each element 30 can be measured. For example, using probes 66a and 66g, and then probes 66g and 66m, twice as many grid areas can be measured. Therefore, each element 30 would be divided in half along line 74d (which is not a scribe, just an indication of a location). As shown, with nine cross-scribe lines 28, twenty grid elements could be tested in ten rows, divided into two columns at line 74d. Appropriate computer control, multiplexer function, and lighting element sequencing could be carried out to obtain the measurements.

As shown, probes 66g along line 74d are single probes, so probes 66g could be used with either probes 66a or 66m at a given time for a measurement. If instead probes 66a, 66d, 66g, 66j, and 66m were used, forty grid elements would be created, divided along scribe lines 28 and lines 74b, 74d, and 74f. However, measurements would be taken in steps (for example, using probes 66a/66d and 66g/66j first, then using probes 66d/66g and 66j/66m) as polarity of probes 66d, 66g and 66j would switch during the steps.

Alternatively some or all probes could be provided in pairs, such as probes 66b and 66c, 66e and 66f, 66h and 66i, and 66k and 66l, or to achieve a desired distribution of elements in view of the number of cells in the photovoltaic device, the capacity of the multiplexer, etc., as mentioned above. Providing closely located pairs allows for testing of more locations at one time, subject only to the limits of the multiplexer and computer capacity. Accordingly, as shown, in one instance grid portions could be measured using probes 66a/66b, 66c/66d, 66g/66h and 66i/66j in one instance, and using probes 66d/66e, 66f/66g, 66j/66k and 66l/66m in a second instance. Note that closely located pairs, such as 66b and 66c, are not used together, but each of the two within such a pair is used with other probes. Probes may contact adjacent cells of photovoltaic device 10 or may skip one or more cells, depending on the number of cells, desired spacing of elements, etc.

Alternately, use of opposites in a pair of elements could be employed to provide overlap in measurements. For example, probes 66a/66c and 66b/66d could be used to cover a given area rather than 66a/66b and 66c/66d.

Many variations are possible. Different groupings of probes could be employed in two or more lighting instances, in numerous ways. If all probes were placed in pairs the one instance could be employed, although a higher amount of parallel processing capacity would be required for the multiplexer and computer. However, alternate usage of a single probes (rather than use of closely mounted pairs) could provide more precision but require more instances of lighting. All such concepts, modifications, and such are within the scope of the present invention.

Apparatus 50 can include components of a SLP-3500 Solar Simulator, available from Spire Solar of Bedford, Mass. For example, light cabinet 51, computer 72, and electrical control cabinet 73 can be obtained in an SLP-3500 device.

Computer 72 can a general purpose computer with an operating system, programming, memory, processors, user interface, and input output connections to the multiplexer, etc. Electrical control cabinet 73 contains electronics for powering the lamp inside the light cabinet 51, and measuring the electrical signals produced by the device under test once the light hits it. This result (the IV trace) is sent to the computer and the computer analyzes it to obtain the relevant performance parameters such as the Voc, FF, Rsh, Efficiency, etc. Computer 72 can tell the multiplexer 70 which channels to use (which effectively chooses which discrete element or elements of device 10 are under test from the grid of possible test areas), and can also communicate with electrical control cabinet 73 to tell it to actually test device 10 and harvest the data.

It should be understood that many variations in the above arrangement can be made. For example, different light cabinet and electrical control devices could be sourced or used. Also, the electrical control cabinet and the computer could be combined in some way, or a programmable logic controller could be added or substituted for some part of the apparatus. Also, a higher capacity of channels in the multiplexer and/or processing and memory capacity in the computer and control devices can reduce the number of instances or steps needed for testing a given device. Therefore, many different computer, control, multiplexing and analyzing systems could be employed according to the present invention without departing from the present disclosure. Use of a grid of discrete elements for testing therefore provides numerous benefits regardless of exactly what apparatus and methods are employed, and how probes are arranged on probe head assembly 60.

The present apparatus can conduct an IV trace on each discrete grid area during each lighting instance, and can create at least one map of the photovoltaic device indicating distribution of a characteristic of the discrete areas based on the IV trace. An IV trace as discussed herein may therefore result in a plot of the given characteristic of an electrical device based on the lighting instance(s). Typically, during a lighting instance, in performing an IV Trace, one would vary in discrete steps one of the current or the voltage across a discrete grid area or areas and measure the other of voltage or current. Performance characteristics of the measured device such as efficiency, V_{oc}, I_{sc} Rₛₕ, Rₛ, fill factor, etc., are extracted by analyzing the generated IV trace plot.

FIG. 11 shows one example of a plot (map) of discrete elements made from an IV trace of a photovoltaic device 10, and FIG. 12 shows the map with interpolation of results between the discrete elements. Such photovoltaic devices in commercial scale often have a size greater than one square meter. For example, photovoltaic devices may be about rectangular with a size of about 0.5-1.5 square meters, although no limitation or size is intended herein. In such a device, using sufficient cross-scribes and probes to create 10, 20, 50, or 80 or more individual elements provides differing levels of information and complexity. FIGS. 10 and 11 show a device and resulting maps with 80 discrete grid elements in an 8×10 arrangement. It should be understood that many other arrangements are possible, with larger or smaller grid elements, unevenly sized grid elements, unevenly distributed grid elements, etc.

Individual grid areas can be tested for efficiency, voltage, current, fill factor, series and shunt resistance, etc. Instead of monolithically testing the entire photovoltaic device, by testing the individual areas more can be learned about the uniformity of the device and accordingly manufacturing accuracy. In principle, using a head assembly with a number of probes and a photovoltaic device that is cross-scribed to electrically isolate portions so as to avoid cross-talk, virtually any characteristic that can be measured based on light impinging on the device can also be measured in the grid, thereby providing localized information, as well as information as to uniformity across the entire device.

It should also be understood that as an option sufficient probes 66 need only be provided to measure a portion of photovoltaic device 10. In such case, if desired, relative movement can be provided between head assembly 60 and the photovoltaic device 10 so that portions of the photovoltaic device can be tested in sequence. Therefore, for example, sufficient probes 66 could be provided to test one-half, one-fourth, etc. of the photovoltaic device 10, and the head assembly 60 and/or photovoltaic device 10 could be relatively moved for sequential testing. The present disclosure thus includes apparatus and methods wherein all or a portion of a photovoltaic device 10 can be tested using a given probe/photovoltaic device placement.

According to the above, a method of evaluating characteristics of a photovoltaic device can be performed including scribing the photovoltaic device with a first plurality of parallel scribes in a first direction to a depth through the back contact layer create a series of discrete linear cells electrically connected in series; scribing the photovoltaic device with a second plurality of parallel scribes in a second direction substantially perpendicular to the first direction to a depth through the back contact layer to electrically isolate material on opposite sides of the second plurality of parallel scribes; contacting the back contact layer with a plurality of pairs of probes arranged in a grid of discrete areas at least partially defined by the second scribing step; illuminating the photovoltaic device; and receiving information from the probes.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

What is claimed is:

1. An apparatus for evaluating characteristics of a photovoltaic device with an exposed back contact layer having a plurality of electrically discrete areas arranged in a grid, the apparatus comprising:
a light source for illuminating the photovoltaic device;
a probe head assembly having a plurality of probes arranged in a grid corresponding to the grid on the photovoltaic device so that a given pair of the probes corresponds to a respective one of the electrically discrete areas within the grid, the probes and photovoltaic device being positionable so that the probes contact the back contact layer; and,
a controller for directing positioning of the probes into contact with the photovoltaic device, activating the light source, and receiving information from probes generated when the light source is activated.

2. The apparatus of claim 1, wherein the controller conducts an IV trace on each discrete area.

3. The apparatus of claim 2, wherein the controller creates at least one map of the photovoltaic device indicating distribution of a characteristic of the discrete areas based on the IV trace.

4. The apparatus of claim 1, wherein the probe head assembly includes probes arranged to measure at least 10 discrete areas.

5. The apparatus of claim 4, wherein the probe head assembly includes probes arranged to measure at least 50 discrete areas.

6. The apparatus of claim 1, wherein the photovoltaic device has a surface area of at least one-half square meter.

7. The apparatus of claim 1, further including a multiplexer in electrical communication between the probes and the controller.

8. The apparatus of claim 7, wherein the probe head assembly includes at probes arranged to measure at least 10 discrete areas.

9. The apparatus of claim 1, wherein the grid encompasses substantially all of the photovoltaic device.

10. A method for evaluating characteristics of a photovoltaic device with an exposed back contact layer, the method comprising:
scribing the photovoltaic device with a first plurality of parallel scribes in a first direction to a depth through the back contact layer to create a series of discrete linear cells electrically connected in series;
scribing the photovoltaic device with a second plurality of parallel scribes in a second direction substantially perpendicular to the first direction to a depth through the back contact layer to electrically isolate material on opposite sides of the second plurality of parallel scribes;
contacting the back contact layer with a plurality of probes arranged in a grid of discrete areas at least partially defined by the second scribing step;
illuminating the photovoltaic device; and,
receiving information from the probes.

11. The method of claim 10, wherein the information received includes an IV trace of each discrete area.

12. The method of claim 11, further including creating at least one map of the photovoltaic device indicating distribution of a characteristic of the discrete areas based on the IV trace.

13. The method of claim 10, wherein the probes are arranged to measure at least 10 discrete areas.

14. The method of claim 13, wherein the probes are arranged to measure at least 50 discrete areas.

15. The method of claim 10, wherein the wherein the photovoltaic device has a surface area of at least one-half square meter.

16. The method of claim 15, wherein the probes are arranged to measure at least 10 discrete areas.

17. The method of claim 16, wherein the probes are arranged to measure at least 50 discrete areas.

18. The method of claim 10, wherein the grid encompasses substantially all of the photovoltaic device.
